(19) United States
(12) Patent Application Publication
(10) Pub. No.: US 2012/0060895 A1
(43) Pub. Date: Mar. 15, 2012

(54) PHOTOVOLTAIC MODULE STRING ARRANGEMENT AND SHADING PROTECTION THEREFOR

(75) Inventors: Leonid Borisovich Rubin, Burnaby (CA); Valery M. Nebusov, Burnaby (CA); Fariborz Fari Ordubadi, North Vancouver (CA)

(73) Assignee: DAY4 ENERGY INC., Burnaby, British Columbia (CA)

(21) Appl. No.: 13/321,536

(22) PCT Filed: May 25, 2009
(86) PCT No.: PCT/CA2009/000728

§ 371 Date: Nov. 18, 2011

(51) Int. Cl. H01L 31/042; H01L 31/05; H01L 31/18; H01L 31/024

(52) U.S. Cl. 136/246; 136/244; 136/251; 438/66; 257/E31.131

(57) ABSTRACT

A method and apparatus for protecting a string of solar cells from shading in a solar panel having a plurality of strings of solar cells are described. Electric current is shunted around any string of the solar cells having at least one shaded solar cell by shunting the electric current through electrical conductors and a bypass diode located in a perimeter margin of a substrate supporting the solar cells such that no matter which string has a shaded solar cell current through the string with the shaded solar cell is shunted through electrical conductors and a respective bypass diode located in the perimeter margin. This distributes dissipation of heat from respective bypass diodes that are associated with strings having at least one shaded solar cell, to different locations around the perimeter margin.

### BACKGROUND OF THE INVENTION

1. Field of Invention

This invention relates to photovoltaic (PV) modules and more particularly to configuring PV cells to permit increasing number of PV strings and providing shading protection of said strings with by-pass diodes located within a PV module.

2. Related Art

The design and production of PV modules comprised of crystalline silicon PV cells has remained virtually unchanged for more than thirty years. A typical PV cell comprises semiconductor material with at least one p-n junction and front and back side surfaces having current collecting electrodes. When a conventional crystalline PV cell is illuminated, it generates an electric current of about 34 mA/cm² at about 0.6-0.62V. A plurality of PV cells is typically electrically interconnected in series and/or in parallel PV strings to form a PV module that produces higher voltages and/or currents than a single PV cell.

PV cells may be interconnected in strings by means of metallic tabs, made for example from tinned copper. A typical PV module may comprise 36-100 PV series interconnected cells, for example, and these may be combined into typically 2 to 4 PV strings to achieve higher voltages than would be obtainable with a single PV cell.

Since PV modules are generally expected to operate outdoors for typically 25 years without degradation, their construction must withstand various weather and environmental conditions. Typical PV module construction involves the use of a transparent sheet of low iron tempered glass covered with a sheet of polymeric encapsulant material such as ethylene vinyl acetate or thermoplastic material such as urethane on a front side of the module, for example. An array of PV cells is placed onto the polymeric encapsulant material in such a way that the front sides of the cells face the transparent glass sheet. A back side of the array is covered with an additional layer of encapsulant material and a back sheet layer of weather protecting material, such as Tedlar® by DuPont, or a glass sheet. The additional layer of encapsulant material and the back sheet layer typically have openings to provide for electrical conductors connected to PV strings in the module to be passed through the back encapsulant layer and back sheet of weather protecting material to provide for connection to an electrical circuit.

For a PV module having an array of two strings of PV cells, typically four conductors are arranged to pass through the openings so that they are all in proximity with each other so they can be terminated in a junction box mounted on the back sheet layer. The glass, encapsulant layers, cells and back sheet layer are typically vacuum laminated to eliminate air bubbles and to protect the PV cells from moisture penetration from the front and back sides and also from the edges. The electrical interconnections of PV strings and connections to bypass diodes are made in the junction box. The junction box is sealed on the back side of the PV module.

PV modules with series-interconnected PV cells perform optimally only when all the series interconnected PV cells are illuminated with approximately similar light intensity. However, if even one PV cell within the PV module layout is shaded, while all other cells are illuminated, the entire PV module is adversely affected resulting in a substantial decrease in power output from the PV module. It was demonstrated (“Numerical Simulation of Photovoltaic Generators with Shaded Cells”, V. Quaschning and R. Hanitsch, 30^{th} Universities Power Engineering Conference, Greenwich, Sep. 5-7, 1995, p.p. 583-586) that a Photovoltaic module comprising 36 PV cells loses up to 70% of the generated power when only 75% of just one PV cell is shaded (less than 3% of the module area). In addition to temporary power loss, the module may be permanently damaged as a result of cell shading because when PV cell is shaded it starts to act as a large resistor rather than a power generator. In this situation, the other PV cells in the PV string expose the shaded cell to reverse voltage that drives electric current through this large resistor. This process may result either in breakdown of the shaded PV cell or heating it to a high temperature that can destroy then entire PV module if this high temperature persists. In order to reduce the risk of PV module damage in the event of shading, practically all PV modules employ by-pass diodes (BPD) connected across each PV string and/or an entire module depending on the specific PV module design and the quality of the PV cells used.

The number of PV cells in a single PV string depends on PV cell quality and more particularly the ability to withstand a reverse voltage breakdown that could occur across all of the solar cells in the string if even one cell within the PV string is shaded. For example for PV cells of good quality that are rated for a reverse breakdown voltage of 14 V and where each PV cell generates a maximum voltage (V max) of about 0.56V the number of PV cells in one string should not exceed 24. For PV cells produced from metallurgical silicon which typically has a lower reverse breakdown of voltage of 7V, it is not recommended to use them in PV strings comprising more than 12 cells. This creates a problem for PV module manufacturers because more complicated PV cell layouts are required and this leads to additional bussing and an increased number of junction boxes. These complications can result in power losses due to increased series resistance.

In order to reduce the power loss caused by bypassing an entire string of cells it is possible to bypass individual cells but this has led to economical and technical problems which have impeded the development of a practical industrial solution. Generally most solutions employ similar principles in which a bypass diode is connected to a PV cell in the opposing direction to the solar cell it protects so that when the solar cell is reverse-biased, the associated bypass diode begins to conduct. This interconnection may employ electrical conductors which connect the diode terminals to the cell terminals or the bypass diode may be directly integrated with the PV cell during fabrication using microelectronics techniques and equipment. Generally, to date, the primary focus of research in this area appears to be to examine ways to miniaturizes the bypass diode in order to minimize PV cell breakage during PV module lamination.

U.S. Pat. No. 6,184,458 B1, to Murakami et al, entitled “Photovoltaic Element and Production Method” describes a PV element formed by depositing a photovoltaic element and a thin film bypass diode on the same substrate whereby the bypass diode does not reduce the effective area of the PV element because it is formed under a screen printed current collecting electrode. The production of such cells is complicated and requires precision alignment between the screen printed current collecting electrode and the bypass diode portion. Furthermore the techniques disclosed would likely not be practical for modern high efficient crystalline silicon PV cells because currently available thin film bypass diodes cannot withstand high currents such as about 8.5 A, that are typical in a high efficiency 6 inch cell. Furthermore, there appears to be no regard for dissipation of heat that is generated in the bypass diode which could cause overheating and eventually cause the diode to fail. Overheating may possibly lead to the destruction of the PV cell and the PV module.

U.S. Pat. No. 5,616,185, 1997, to Kukulka entitled “Solar Cell with Integrated Bypass Diode and Method” describes an integrated solar cell bypass diode assembly that involves forming at least one recess in a back (non-illuminated) side of a solar cell and placing discrete low-profile bypass diodes in respective recesses so that each bypass diode is approximately coplanar with the back side of the solar cell. The production methods described are complicated and require precision grooves to be cut in the solar cell. The grooves can make the solar cell fragile, increasing cell breakage and yield losses. Again, the techniques described in this reference would likely not be practical for modern high efficient crystalline silicon PV cells because thin film bypass diodes generally cannot withstand the high currents typically found with such cells, or the resultant heating caused by such high currents.

U.S. Pat. No. 6,384,313 B2, 2002, to Nakagawa et al. entitled “Solar Cell Module and Method of Producing the Same” describes a method of forming a light-receiving portion of a solar cell element and a bypass diode on the same side of the substrate on which the solar cell is formed. A solar cell with these features allows for series connection of a plurality of solar cell units from only one side of the substrate.

U.S. Pat. No. 5,223,044 1993, to Asai entitled “Solar Cell Having a By-Pass Diode”, provides a solar cell having only two terminals and an integrated bypass diode formed on a common semiconductor substrate on which the solar cell is formed. Again, the techniques described in the above two patents require complicated and costly microelectronic technological approaches not easily incorporated into a production line and the bypass diodes created would likely not be able to withstand the high current and resulting heat that can occur when the bypass diode is required to conduct current.

U.S. Pat. No. 6,784,358 B2, 2004, to Kukulka entitled “Solar Cell Structure Utilizing and Amorphous Silicon Discrete By-Pass Diode”, describes a solar cell structure with protection against reverse-bias damage. The protection employs a discrete amorphous silicon bypass diode with a thickness that does not exceed 2-3 microns so that it protrudes from a surface of the solar cell by only a small distance and does not protrude from the sides of the solar cell. The terminals of the amorphous semiconductor bypass diode are electrically connected by soldering, to corresponding sides of an active semiconductor structure. The soldering of such extremely thin and fragile diodes to the active semiconductor substrate requires extreme accuracy in order to avoid diode breakage. In addition, the amorphous semiconductor bypass diode cannot withstand the high currents and resulting temperatures that can occur in crystalline silicon solar cell systems.

U.S. Pat. No. 5,330,583, to Asai et al. entitled “Solar Battery Module”, describes a solar battery module that includes interconnectors for series-connecting a plurality of solar battery cells, and one or more bypass diodes which allow output currents of the cells to be bypassed around one or more cells. Each diode is a chip-shaped thin diode and is attached on an electrode of a cell or between interconnectors. More particularly, the chip-shaped bypass diodes are either connected to a front surface of the solar battery or are positioned to the side of a solar battery or are connected to rear surface of a solar battery to protect a string of solar batteries. When the bypass diodes are connected to the front surface, they are soldered directly to one of two parallel conductors which appear to be bus bars, on the front surface of the solar cell. Generally in solar cell design it is an objective to keep the front face of the solar cell clear to keep shading of the front surface to a minimum. Current collecting fingers and bus bars connected to the fingers to gather current from the solar cell are usually the only things acceptable to occlude the front surface, due to their necessity. Generally, fingers and bus bars have width and length dimensions that keep the area they occupy on the front surface to a minimum. Therefore bus bars typically have a narrow width and as a result, the bypass diodes of Asai are necessarily small in width. Although bypass diodes with such a small width and length may be able to carry relatively large currents, due to their small area they tend to heat up due to current flow and impose a localized extreme heat source on the solar cell to which they are mounted.

US 2005/0224109 A1, to Jean P. Posbic and Dinesh S. Amin entitled “Enhanced function photovoltaic modules” describes PV modules comprising at least one thin printed circuit board with a dielectric substrate and specially designed metalized patterns positioned within the PV module. There can be one or more such boards in the module. The length of the board can be about 500 to about 2000 mm and its width can be about 10 to about 50 mm and its thickness may be about 0.1 to about 2 mm. In one embodiment one or more by-pass diodes are electrically connected to the board and to corresponding PV strings of the PV module thus providing shading protection. Although this invention allows imbedding by-pass diodes inside the PV module and improves its shading protection it decreases PV module efficiency due to the area that printed circuit board occupies inside the module. It is also appears that the heat dissipation capacity of this circuit board is limited because its metallic part occupies only part of its thickness while its substrate is made from dielectric material.

It is known that after installation the lower part of a PV module has a greater chance of being shaded due to accumulation for example of dirt, snow or even by not cutting grass near the PV module where it is installed in a field. The present invention allows special layout of PV cells within a PV module to achieve minimal power losses if any small part and especially the lower part of the PV module is shaded. Such layouts may increase the number of PV strings that are equipped with individual by-pass diodes. For example, if a PV module comprises 60-cells that are arranged in 3 PV strings each of 20 cells and only one cell is shaded then the PV module will decrease its power generation at least by 33%. However if these 60 cells are arranged in 10 strings, then shading of one cell will result in just 10% power loss.

### SUMMARY OF THE INVENTION

In accordance with one aspect of the invention, there is provided a solar panel apparatus including a transparent sheet substrate having front and rear planar faces and a perimeter edge extending all around a perimeter of the substrate, a plurality of solar cells arranged into a planar array on the rear face such that light operable to activate the solar cells can pass though the substrate to activate the solar cells and such that a perimeter margin is formed on the rear face of the substrate, adjacent the perimeter edge. A plurality of electrical conductors is arranged generally end to end in the perimeter margin. A plurality of electrodes electrically connects the solar cells together into a plurality of series strings of solar cells, each series string having a positive terminal and a negative terminal electrically connected to respective ones of an adjacent pair of electrical conductors adjacent to each other, in the perimeter margin. The apparatus further includes a plurality of bypass diodes, each of the bypass diodes being electrically connected between a respective pair of electrical conductors to shunt current from a corresponding string connected to the respective pair of electrical conductors when a solar cell of the corresponding string is shaded.

The strings may be electrically connected in a series, such that the series has a first string and a last string and wherein a first solar cell of the first string and a last solar cell of the last string are disposed proximally adjacent each other.

The first solar cell of the first string and the last solar cell of the last string may be disposed adjacent a common edge of the substrate.

The strings may be electrically connected together by electrodes, to form the series.

The bypass diodes may include planar diodes.

The apparatus may further include heat sinks to dissipate heat caused by electric current flowing in respective bypass diodes.

The electrical conductors may include respective heat sink portions that act as the heat sinks. In operation, respective bypass diodes may have a thermal gradient defining a hot side and a cold side thereof and the respective bypass diodes may have a hot side terminal and a cold side terminal emanating from the hot side and the cold side respectively. The hot side terminal may be connected to a respective heat sink portion of a respective one of the electrical conductors.

The respective heat sink portions may include respective generally flat portions of the electrical conductors.

The electrical conductors may include a first type of metallic foil strip and the generally flat portions may have a thickness of between about 50 μm to about 1000 μm and a width of between about 3 mm to about 13 mm and a length of between about 3 cm to about 200 cm.

The apparatus may further include terminating conductors associated with respective bypass diodes and the terminating conductors may include a metallic foil strip of a second type having a thickness less than the thickness of the generally flat portion of the metallic foil strip of the first type and a length less than the length of the generally flat portion of the metallic foil strip of the first type. The metallic strip of the second type may have a first end connected to a respective one of the electrical conductors and a second end connected to the cold side of a respective bypass diode.

The metallic foil strip of the second type may have a thickness of between about 30 um to about 200 um, a width approximately the same as the width of the metallic foil of the first type and a length of between about 3 cm to about 10 cm.

Alternatively, the electrical conductors may be formed from a third type of metallic foil strip having a thickness of between about 30 μm to about 200 μm and a width of between about 3 mm to about 13 mm and a length of between about 3 cm to about 200 cm. The heat sinks may include respective metallic foil strips of a fourth type electrically connected to respective metallic foil strips of the third type and the metallic foil strips of the fourth type may have a thickness greater than the thickness of the metallic foil strips of the third type.

The metallic foil strip of the fourth type may have a width approximately the same as the width of the metallic foil strip of the third type and a length less than the length of the metallic foil strip of the third type.

The metallic foil strip of the fourth type may be on a portion of a respective metallic foil strip of the third type.

In operation, respective bypass diodes may have a thermal gradient defining a hot side and a cold side thereof and the respective bypass diodes may have a hot side terminal and a cold side terminal emanating from the hot side and the cold side respectively. The hot side terminal may be electrically connected to a respective metallic foil strip of the fourth type and the cold side terminal may be electrically connected to a respective metallic foil strip of the third type.

The metallic foil strip of the fourth type may have a thickness of between about 50 μm to about 1000 μm and a width approximately equal to the width of the metallic foil strip of the first type and a length of between about 3 cm to about 200 cm.

The apparatus may further include a backing covering the solar cells, the electrical conductors and the bypass diodes, such that the solar cells, the electrical conductors and the bypass diodes are laminated between the front substrate and the backing to form a laminate.

The backing may have an impregnated heat conducting material operable to conduct heat from the electrical conductors and the bypass diodes.

The backing may include aluminum-impregnated Tedlar®.

The apparatus may further include a heat conductive frame on the perimeter edge.

The frame may be operable to mechanically support the panel.

The first and last strings may have respective terminals that extend from between the front substrate and the backing, to extend from an edge of the laminate.

The solar cells may be arranged in rows and columns on the substrate and the apparatus may have a bottom and a top. The bottom may be operable to be mounted lower than the top when the solar panel apparatus is in use, and solar cells in a bottom row located at the bottom may be electrically connected by the electrodes to define a bottom string of solar panels.

Solar cells in at least first and second rows of the solar cells, above the bottom row and in at least some of the columns of the solar cells common to the bottom row may be electrically connected together to define a mid-string of solar cells, wherein the mid-string includes a first solar cell and a last solar cell at opposite poles of the mid-string, and wherein the first and last solar cells of the mid-string are in a same column of the solar cells and are in adjacent rows of the solar cells.

The plurality of series strings may include a plurality of mid-strings.

Some of the mid-strings may be disposed side by side.

The first solar cell of the first string and the last solar cell of the last string may be disposed at the top of the substrate.

In accordance with another aspect of the invention, there is provided a method of protecting a string of solar cells from shading in a solar panel having a plurality of strings of solar cells. The method involves causing electric current to be shunted around any string of the solar cells having at least one shaded solar cell by shunting the electric current through electrical conductors and a bypass diode located in a perimeter margin of a substrate supporting the solar cells such that, no matter which string has a shaded solar cell, current through the string with the shaded solar cell is shunted through electrical conductors and a respective bypass diode located in the perimeter margin to thereby distribute dissipation of heat from bypass diodes associated with respective strings having at least one shaded solar cell to different locations around the perimeter margin.

Causing electric current to be shunted may involve arranging a plurality of solar cells into a planar array on a rear face of a transparent sheet substrate having front and rear faces and a perimeter edge extending all around a perimeter of the substrate, such that light can pass though the substrate to activate the solar cells and such that the perimeter margin is formed on the rear face of the substrate adjacent the perimeter edge. A plurality of electrodes electrically connect the solar cells together into a plurality of series strings of solar cells wherein each series string has a positive terminal and a negative terminal.

The method may further involve connecting the solar cells with the electrodes such that the first solar cell of the first string and the last solar cell of the last string are disposed at the top of the substrate.

The present invention may provide more optimal and efficient shading protection of PV modules.

The present invention may also provide the possibility of varying not only the number of PV strings but also the number of cells in each string depending on the type of PV cells, or PV module and shading conditions at the installation site.

It has been found that with electrical conductors with dimensions as recited above sufficient heat dissipation is provided. The use of the backing with aluminum foil for example such as provided by a product known as Tedlar® from Isovolta, Austria, provides additional heat dissipation from the by-pass diodes and electrical conductors through the back side of the PV module which keeps the temperature of the by-pass diodes generally below 120° C. in field conditions when any PV cell in any PV string is shaded.

The electrical conductors and by-pass diodes are positioned in close proximity to the edges of the PV module which provides for sufficient electrical insulation for the PV module.

The electrical conductors do not conduct electric current when all PV cells are under equal illumination but do carry electric current when a solar cell of any string is shaded.

A connection between terminal leads of the module and the external load may be provided by allowing the terminal leads to extend either through a hole or holes in the back sheet or through the edge of the laminate.

By extending the terminal leads out the edge of the laminate the need for a conventional junction box on the rear surface of the module, can be eliminated thereby decreasing the complexity and cost of PV module production.

### DETAILED DESCRIPTION

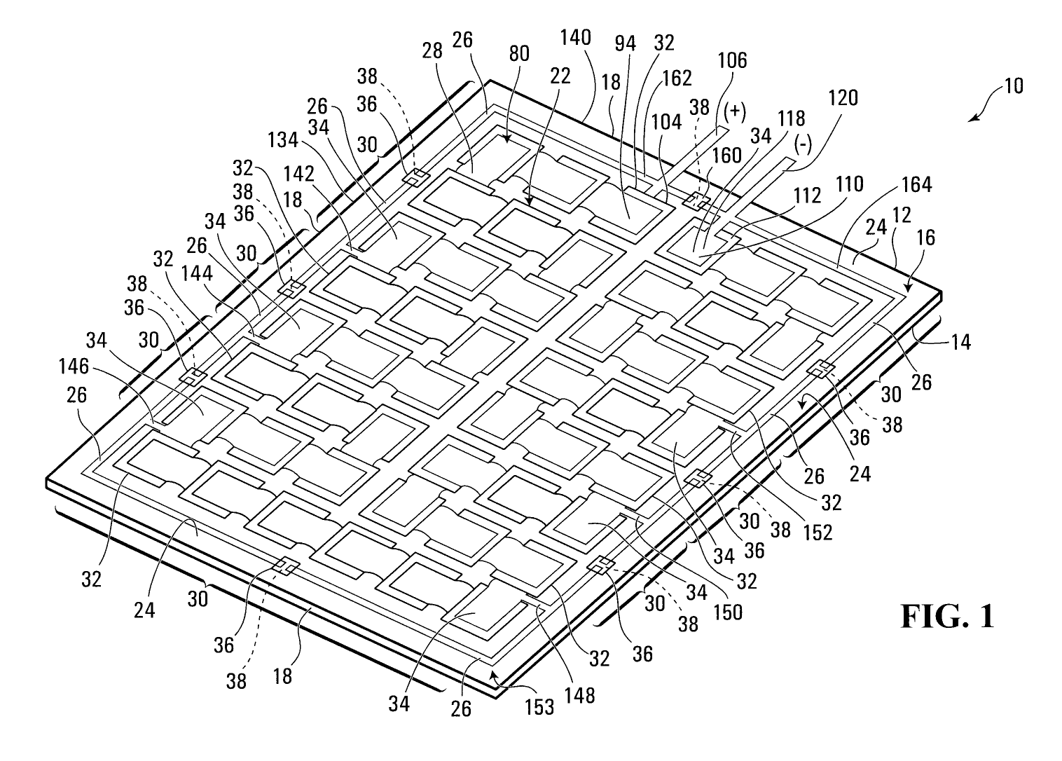

Referring to FIG. 1, a solar panel apparatus according to a first embodiment of the invention is shown generally at 10. The apparatus 10 comprises a transparent sheet substrate 12 having front and rear planar faces 14 and 16 and a perimeter edge 18 extending all around a perimeter of the substrate 12.

The apparatus 10 further includes a plurality of solar cells 22 arranged into a planar array on the rear planar face 16 such that light operable to activate the solar cells 22 can enter the front face 14 of the substrate and pass though the substrate 12 to activate the solar cells 22 and such that a perimeter margin 24 is formed on the rear planar face 16 of the substrate 12, adjacent the perimeter edge 18.

The apparatus 10 further includes a plurality of electrical conductors 26 arranged generally end to end in the perimeter margin 24. The apparatus 10 further includes a plurality of electrodes 28 electrically connecting the solar cells 22 together into a plurality of series strings 30 of solar cells 22, each series string 30 having a positive terminal 32 and a negative terminal 34 electrically connected to respective ones of an adjacent pair of electrical conductors 26 adjacent to each other, in the perimeter margin 24. The electrodes 28 are generally as described in applicant's International Patent Publication No. WO 2004/021455A1 published Mar. 11, 2004.

The apparatus 10 further includes a plurality of bypass diodes 36. Each of the bypass diodes 36 is electrically connected between a respective pair of electrical conductors 26 to shunt current from a corresponding string 30 connected to the respective pair of electrical conductors when a solar cell 22 of the corresponding string is shaded.

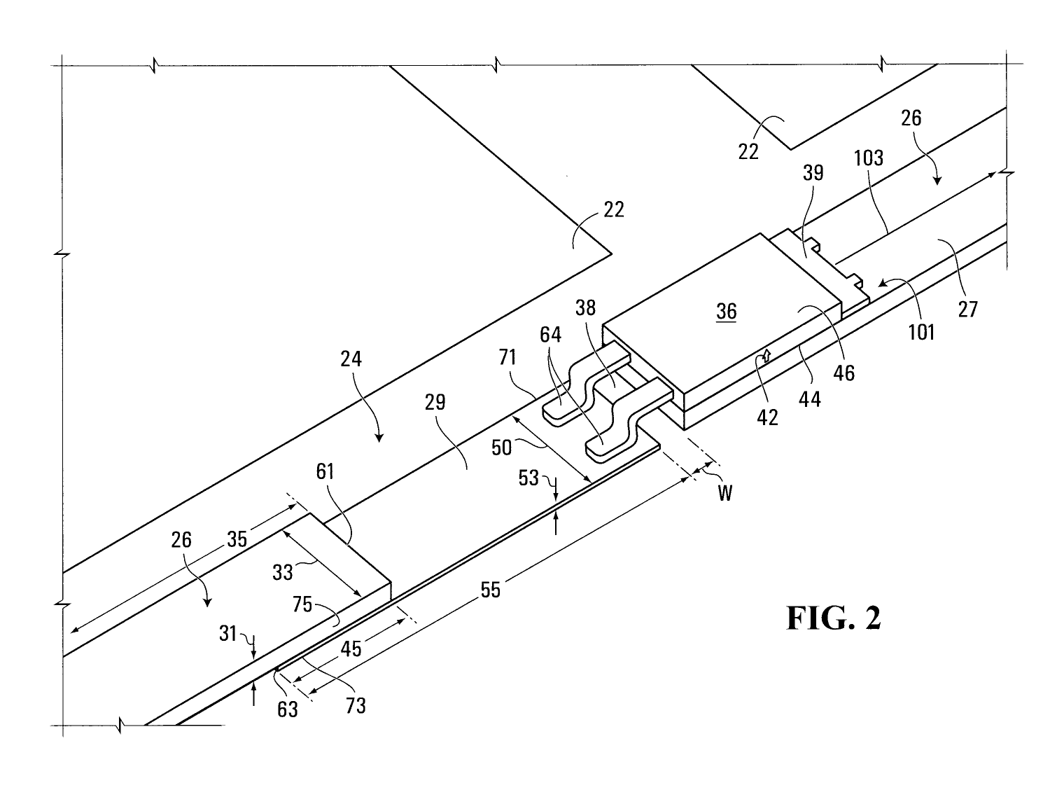

Referring to FIG. 2, the apparatus (10) further includes heat sinks 101 to dissipate heat caused by electric current flowing in respective bypass diodes 36. Each diode 36 has an associated heat sink 101. In the embodiment shown, each electrical conductor 26 includes a respective heat sink portion 103 that acts as the heat sink 101.

In the embodiment shown, the bypass diodes 36 are flat planar bypass diodes such as available from Nihon Inter Electronics Corporation of Japan under part No. UCQS30A045 or from Diodes Inc of Dallas Tex., USA, under part No. PDS1040L. When the bypass diode 36 is in operation it has a thermal gradient 42 defining a hot side 44 and a cold side 46 of the bypass diode. The bypass diode 36 thus may be regarded as having a hot side terminal 39 and a cold side terminal 64 emanating from the hot side 44 and the cold side 46 respectively. The hot side terminal 39 is electrically connected to a respective heat sink portion 103 of a respective electrical conductor 26.

In the embodiment shown the heat sink portions 103 include respective generally flat portions 27 of the electrical conductors 26. The flat portions 27 extend the entire length of the electrical conductors 26, but need not do so. In this embodiment, the electrical conductors 26 are comprised of a first type of metallic foil strip and the generally flat portions 27 have a thickness 31 of between about 50 μm to about 1000 μm and a width 33 of between about 3 mm to about 13 mm and a length 35 of between about 3 cm to about 200 cm. Thus the hot side terminal 39 of each bypass diode 36 is electrically connected to a respective flat portion 27 of an electrical conductor 26 such as by soldering, so that heat from the bypass diode can be dissipated along the length of the electrical conductor. The flat portion 27 provides a heat transfer surface to transfer heat to a backing portion as will be described below.

The apparatus further includes terminating conductors 29 associated with the bypass diodes 36. The terminating conductors 29 are comprised of a metallic foil strip of a second type having a thickness 53 less than the thickness 31 of the generally flat portion 27 of the metallic foil strip of the first type and a length 55 less than a length 35 of the generally flat portion of the metallic foil strip of the first type. The terminating conductor 29 has a first end 73 electrically connected to a respective one of the electrical conductors 26 such as by soldering, and a second end 71 electrically connected to the cold side terminal 64 of the respective bypass diode 36 such as by soldering. In the embodiment shown the metallic foil strip of the second type has a thickness 53 of between about 30 um to about 200 um, a width 50 approximately the same as a width of the metallic foil of the first type and a length 55 of between about 3 cm to about 10 cm and is thinner than the metallic foil strip of the first type.

It will be appreciated that by electrically connecting the hot side terminal 39 first to the flat portion 27 of the electrical conductor 26 of the first type, since the electrical conductor of the first type is thicker than the terminating conductor 29 formed from the metallic foil of the second type, the bypass diode 36 is held relatively rigidly by the electrical conductor and the terminating conductor can be used to overcome any misalignment between the opposing electrical conductors to which the bypass diode is ultimately electrically connected.

The terminating conductors 29 are arranged on the perimeter margin 24 such that the second end 71 lies under the cold side terminal 64 of a respective bypass diode 36, but spaced apart from a first adjacent electrical conductor 26 by a gap 38 and the second end 73 lies under a second adjacent electrical conductor 26. A portion 75 of the conductor 26 overlaps the second end 73 of the terminating conductor 29 such that an end edge 61 of the electrical conductor and an end edge 63 of the terminating conductor are spaced apart by a distance 45 of between about 5 mm and about 15 mm.

The gap 38 must be of sufficient width to prevent arcing when the conductors 26, 29 on opposite sides of the gap are subjected to a rated voltage of the system in which the solar panel is installed. Typically a gap of between about 2 to about 3 mm will be sufficient for about a 100 volt potential difference across the gap 38.

The positioning of the electrical conductors 26 and the positioning and number of bypass diodes 36 is determined by the number and arrangement of strings 30 of solar cells 22 in the apparatus 10 because each string is intended to have its own bypass diode.

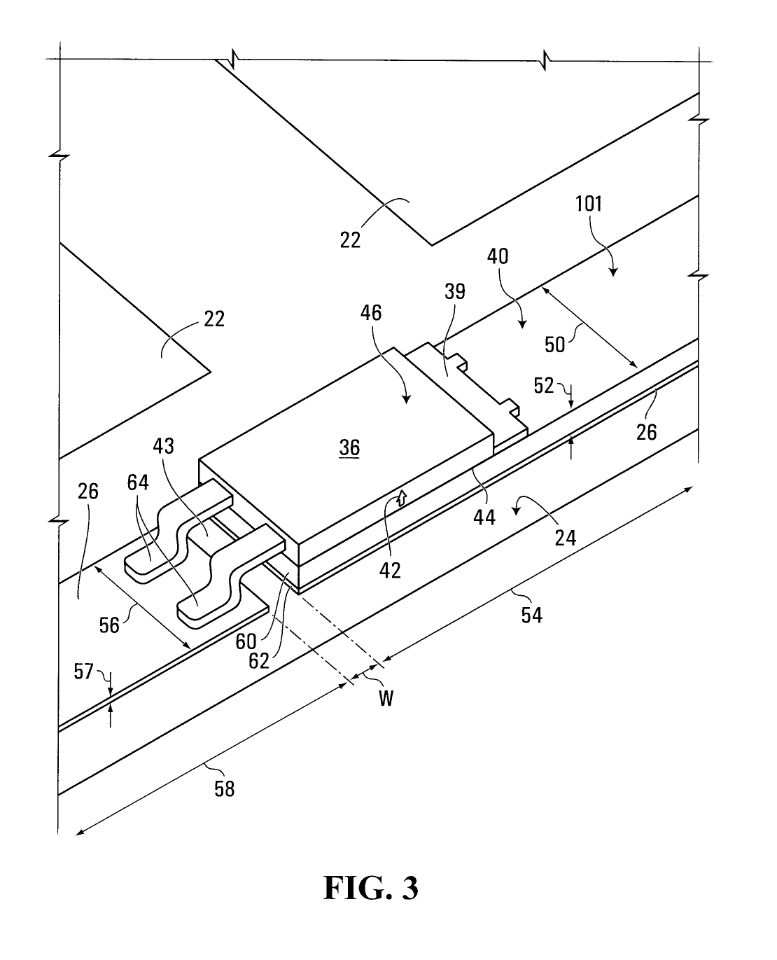

Referring to FIG. 3, in an alternative embodiment, the electrical conductors 26 are formed from a third type of metallic foil strip having a thickness 57 of between about 30 μm to about 200 μm and a width 56 of between about 3 mm to about 13 mm and a length 58 of between about 3 cm to about 200 cm. Thus the electrical conductors 26 in this embodiment are like the thin terminating conductors 29 described above, only longer. The metallic foil strip of the second type described above is similar to the metallic foil strip of the third type used in this embodiment.

In this embodiment, the heat sinks 101 include respective metallic foil strips of a fourth type 40 connected such as by soldering, to respective metallic foil strips of the third type. The metallic foil strips of the fourth type 40 have a thickness 52 greater than the thickness 57 of the of metallic foil strips of the third type and in the embodiment shown, the metallic foil strip of the fourth type 40 has a width 50 approximately the same as the metallic foil strip of the third type and a length 54 less than the length 58 of the metallic foil strip of the third type. The metallic foil strip of the fourth type 40 has a thickness 52 of between about 50 μm to about 1000 μm and a width 50 approximately equal to the width 56 of the metallic foil strip of the third type and a length 54 of between about 3 cm to about 10 cm and thus is thicker than the metallic foil strip of the third type and is similar to the metallic foil strip of the first type.

The bypass diodes 36 are first electrically connected to heat sinks 101 and then the heat sinks are electrically connected to their respective electrical conductors 26. The electrical conductors 26 are positioned on the perimeter margin 24 of the substrate to leave gaps 43 between adjacent electrical conductors 26, where necessary, to permit connection of terminals 64 extending from the cool side 46 of the bypass diodes 36 to the electrical conductors on the sides of the gaps 43 opposite the sides on which the heat sinks 101 are located. The terminals 64 extending from the cool sides 46 of the bypass diodes 36 are connected to respective electrical conductors 26 by soldering.

The gaps 43 must be of sufficient width to prevent arcing when the adjacent conductors 26 on opposite sides of the gap are subjected to a rated voltage of the system in which the solar panel is installed. Typically a gap 43 of between about 2 to about 3 mm will be sufficient for about a 100 volt potential difference across the gap.

The metallic foil strip of the fourth type 40 is on a portion of a respective metallic foil strip of the third type and is secured thereto by soldering, for example, such that an end edge 60 of the metallic foil strip of the fourth type and an end edge 62 of the respective electrical conductor 26 to which it is connected are generally co-planar. Thus, since the electrical conductors 26 are much longer than the metallic foil strips of the fourth type 40, the metallic foil strips of the fourth type extend only a portion of the way along the respective electrical conductor 26 to which they are connected.

The hot side terminals 39 of the bypass diodes 36 are thermally and electrically connected to the heat sink 101 provided by the metallic foil strip of the fourth type 40 such as by soldering, and the cold side terminals 64 are connected to the electrical conductor 26 provided by a metallic foil strip of the third type such as by soldering.

Again, the positioning of the electrical conductors 26 and the positioning and number of bypass diodes 36 is determined by the number and arrangement of strings 30 of solar cells 22 in the apparatus 10 because each string is intended to have its own bypass diode.

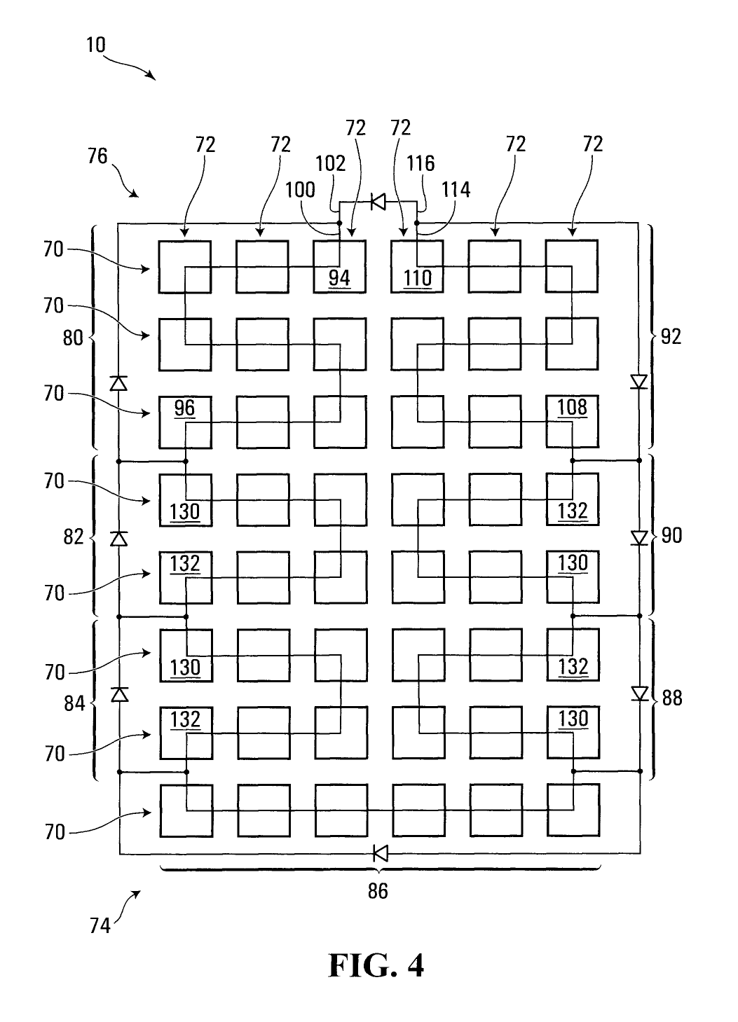

Referring to FIG. 4, in the embodiment shown, the solar cells 22 are arranged in rows 70 and columns 72 on the substrate (shown at 12 in FIG. 1). The apparatus 10 may be regarded as having a bottom 74 and a top 76, wherein the bottom is operable to be mounted lower than the top when the solar panel apparatus 10 is in use. Typically, solar panels are rectangular, having a short side and a long side and are usually mounted such that the short sides are at the top and bottom of the panel. The solar panels are usually connected to mounting structures that hold the solar panels upright at an angle to the vertical. The rows 70 and columns 72 are defined such that rows extend generally horizontally and the columns extend generally vertically, when the panels are in use.

In the embodiment shown, the solar panel apparatus 10 has 48 solar cells electrically connected together by electrodes (shown at 28 in FIG. 1), to form a series group of first, second, third, fourth, fifth, sixth and seventh strings 80, 82, 84, 86, 88, 90 and 92. The first string 80 has first and last solar cells 94 and 96 and a plurality of solar cells in between, all connected in series by the electrodes (28). The first solar cell 94 has a front face facing onto the substrate (12) that acts as a positive terminal 100 for the string 80 and also as a positive terminal 102 for the entire apparatus 10. Thus, a first terminating electrode seen best at 104 in FIG. 1 is connected to the front face of the first solar cell 94 of the first string 80. The first terminating electrode 104 has a first flat planar conductor 106 that extends outwardly, away from the substrate 12, for connection to a positive terminal connector (not shown), for example to enable the positive terminal 102 of the solar panel to be connected to an external circuit.

Similarly, the seventh (last) string 92 has first and last solar cells 108 and 110 and a plurality of solar cells in between, all connected in series by the electrodes (28). The last solar cell 110 has a rear face (112) that acts as a negative terminal 114 for the last string 92 and also as a negative terminal 116 for the entire panel. Thus, a second terminating electrode seen best at 118 in FIG. 1 is connected to the rear face (112) of the last solar cell 110 of the last string 92. The last terminating electrode (118) has a second flat planar conductor (120) that extends outwardly, away from the substrate (12), for connection to a negative terminal connector (not shown), for example, to enable the negative terminal of the solar panel to be connected to the external circuit.

In the embodiment shown, the strings 80-92 are arranged to start with the first string 80 at the top left hand side of the apparatus 10, with the second and third strings 82 and 84 following downwardly on the left hand side. The second and third strings 82 and 84 may be regarded as mid-strings. Each mid-string includes a first solar cell 130 and a last solar cell 132 at opposite poles of the mid-string, and the first and last solar cells 130 and 132 of the mid-string are in a same column 72 and are in adjacent rows 70. By positioning the first and last solar cells 130 and 132 of the mid strings in a same column 72 and adjacent rows 70, the first and last solar cells of each mid-string may be located adjacent an edge of the solar panel, in this case a left-hand edge (looking from the rear), such as shown at 134 in FIG. 1, and thus adjacent the perimeter margin (24), to facilitate connection of the first and last solar cells 130 and 132 of each mid-string to respective electrical conductors (26) and bypass diodes (36) in the perimeter margin (24).

The fourth string 86 is comprised of a row of solar cells at the bottom 74 of the apparatus 10. The fifth and sixth strings 88 and 90 extend up the right hand side of the apparatus 10 and act as additional mid-strings having first and last solar cells 130, 132 that are disposed adjacent the perimeter margin (24). The fifth and sixth strings 88 and 90 are side-by-side with the third and second strings 84 and 82 respectively. The seventh string 92 is the last string which is positioned in the top right hand area of the apparatus 10. Thus, the first and last strings 80 and 92 are disposed adjacent each other in the top portion 76 of the apparatus 10.

In addition, the last solar cell 110 of the last string 92 is proximally disposed adjacent the first solar cell 94 of the first string 80 and this enables the first and second flat planar conductors connected to the positive and negative terminals (100, 114) of the first and last strings respectively to be disposed adjacent each other to permit the positive and negative terminal connectors of the panel to be positioned close to and adjacent each other. In the embodiment shown, the first solar cell 94 of the first string 80 and the last solar cell 110 of the last string 92 are disposed adjacent a common edge, i.e. the top edge (shown at 140 in FIG. 1), of the substrate 12, which enables the positive and negative terminals 102 and 116 for the panel to be located at the top edge (140) of the solar panel.

With the solar cells and strings arranged and connected as described above, it should be appreciated that the first and last solar cells of each string 80-92 are located adjacent the perimeter margin (24). This enables additional electrical conductors such as shown at 142, 144, 146, 148, 150, 152 in FIG. 1 to be electrically connected to the electrodes connecting adjacent strings together to extend into the perimeter margin (24) and connect to corresponding electrical conductors (26) in the perimeter margin, which are electrically connected to bypass diodes (36) for respective strings 80-92.

The electrical conductors (142-152) connecting the electrodes to the electrical conductors 26 in the perimeter margin 24 are desirably about the same width and thickness as the electrical conductors 26 in the perimeter margin, but have lengths, as appropriate, to extend between the electrical conductors in the adjacent perimeter margin and the electrodes 28 electrically connecting adjacent strings 80-92 of the series together.

Referring back to FIG. 1, in the embodiment shown, a group bypass diode 160 is also provided to provide for shunting electric current past the entire group when about 50% of the solar cells in the entire panel are shaded for example. The group bypass diode 160 may be located outside the substrate in a junction box, in the conventional manner, but this diode 160 may alternatively be incorporated on the substrate 12 as shown. To do this, electrical conductors 162 and 164 in the perimeter margin 24 adjacent the top edge 140 are connected to the first and second planar conductors 106 and 120 respectively. As before, leads (not shown) extending from a hot side (not shown) and a cool side (not shown) of the group bypass diode 160 may be connected in the same ways as for the bypass diodes 36, as described above.

Thus, during manufacturing of the apparatus 10, the electrical conductors 142-152 extending from the electrodes 28 connecting the strings together extend into the perimeter margin 24 and are laid on respective electrical conductors 26 in the perimeter margin. The electrical conductors 26 are then positioned to locate the bypass diodes 36 relatively evenly spaced around the perimeter margin 24 and then the electrical conductors 142-152 extending from the electrodes 28 connecting the strings 80-92 together are soldered to the electrical conductors 26 in the perimeter margin 24. It should be appreciated that some of the electrical conductors 26 in the perimeter margin 24 will be aligned longitudinally, such as the electrical conductors 26 in the portions of the perimeter margin 24 associated with the long sides of the solar panel while others of the electrical conductors will be aligned at right angles to extend around corners in the perimeter margin as shown generally at 153. Connection of the electrical conductors 26 that meet at right angles may be achieved by soldering, or ultrasonic welding for example.

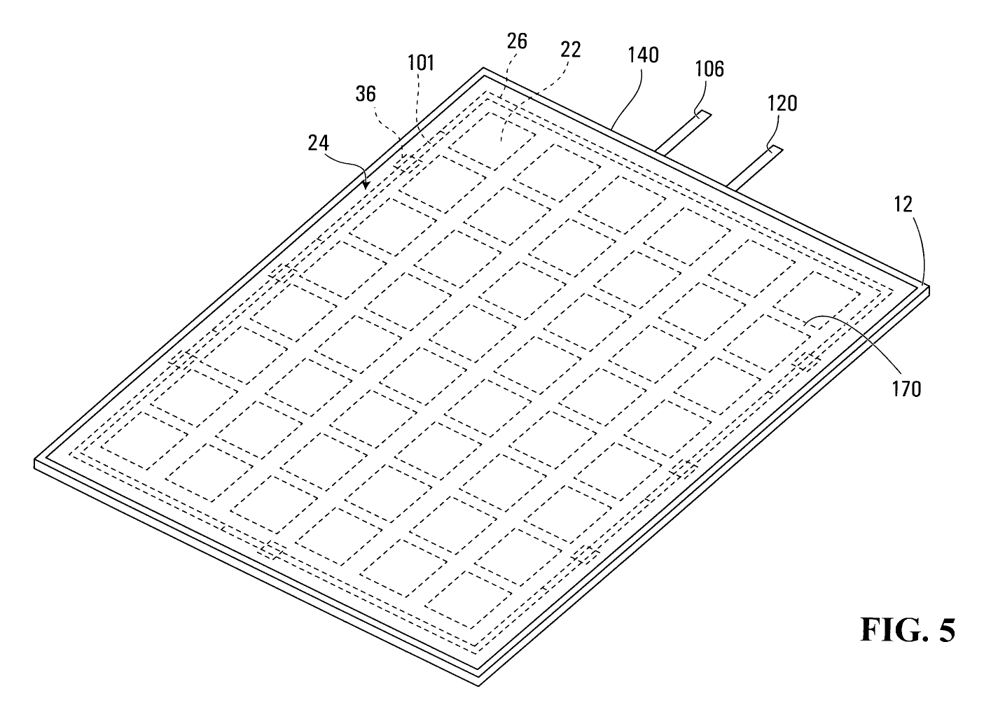

Referring to FIG. 5, after the electrical conductors 26 in the perimeter margin 24 and bypass diodes 36 have been connected as required, a backing 170 is positioned over the substrate 12 to cover the solar cells 22, the electrical conductors 26 and the bypass diodes 36 to form a laminate with the electrodes, solar cells, conductors, heat sinks and bypass diodes sandwiched between the substrate 12 and the backing 170. The backing 170 desirably has an impregnated heat conducting material operable to conduct heat from the heat sinks 101 and from the bypass diodes. The backing 170 may be aluminum-impregnated Tedlar®, for example.

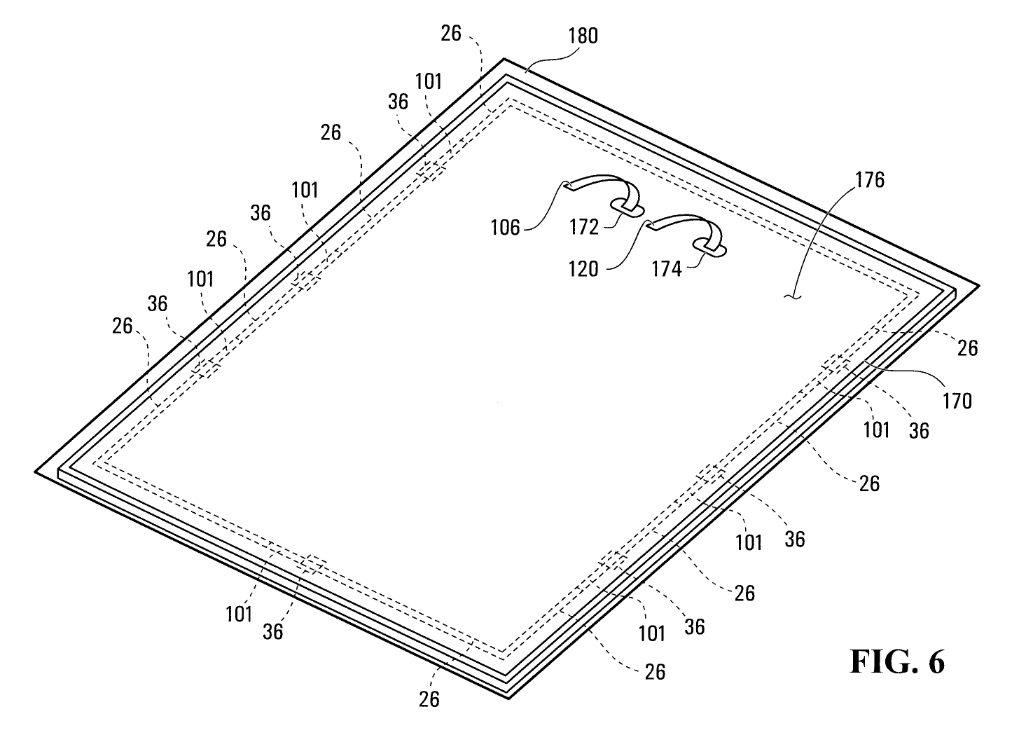

The positive and negative terminal conductors 106 and 120 may extend from between the front substrate 12 and the backing 170, to extend from the top edge 140 of the laminate for termination. Or, referring to FIG. 6, an opening or openings 172 and 174 may be cut in a rear face 176 of the backing 170 to allow the positive and negative terminal conductors 106 and 120 to extend there through and from the rear face 176 of the backing, for termination in a conventional junction box such as provided by Tyco Electronics Ltd, for example, as is commonly used on solar panels.

Desirably, the entire apparatus is laminated such as by conventional techniques for laminating solar panels, to form the laminate. A heat conductive frame 180 may be disposed around the perimeter of the laminate to protect edges of the laminate and to dissipate heat from the bypass diodes 36, the heat sinks 101 and the backing 170. The frame 180 may be made of Aluminum for example and may facilitate mechanical support for mounting the panel.

The lengths of the heat sinks 101 mentioned above, in combination with the heat dissipation properties of the backing 170 and frame 180 are sufficient to adequately dissipate heat produced by the bypass diodes 36 to maintain junction temperatures of the bypass diodes within manufacturer-recommended operating ranges.

A particular advantage of the string arrangement shown in FIGS. 1, 4, 5 and 6 embodiment is that each string 80-92 is separately bypassed and the bottom row of solar cells i.e. the fourth string 86 is a unitary string. Referring to FIG. 4, in installations where the bottom row of solar cells i.e. the fourth string 86 could be deprived of light due to snow or foliage, for example, that string will be bypassed, without affecting the normal operation of the remaining strings 80-84 and 88-92 in the panel. When the fourth string 86 is bypassed, the bypass diode 36 protecting this string will start to heat up and the heat sink to which it is connected will dissipate this heat to the backing 170 and to the frame 180, which can melt the snow, to provide a self-clearing effect.

In the event that snow is not cleared or foliage is permitted to continue to grow in the vicinity of the bottom 74 of the apparatus 10, as the shading caused by snow or foliage rises higher and higher, eventually, the third and fifth strings 84 and 88 will become shaded and bypassed, but still the remainder of the strings, i.e. the first 80, second 82, sixth 90 and seventh 92 strings will still operate. Thus, initially, when only the fourth string 86 is shaded, the apparatus 10 is still able to provide 42/48=87.5% (less losses due to the bypass diode) of its power capacity and when the third and fifth strings 84 and 88 are also shaded, the solar panel is still able to provide about 50% of its power capacity.

As the strings 80-92 are comprised of solar cells (22) connected in series, the maximum reverse voltage that will appear across any shaded solar cell in a string is the sum of the voltages produced by the remaining solar cells in the string plus the bypass diode forward voltage drop. In the embodiment shown, the strings 80-92 are each comprised of 6-9 solar cells (22). This relatively low number of solar cells (22) in each string results in a low maximum reverse voltage on any shaded solar cell of the string. As a result, with say 6 solar cells (22) in a string, when one is shaded, the remaining five solar cells each produce a voltage of 0.56V, resulting in a total voltage contribution of 2.8V from the unshaded cells of the string plus a voltage drop of 0.7V across the bypass diode (36) due to current from the remaining strings of the module, resulting in a total reverse voltage of 3.5V across the shaded cell. The above described technique of bypassing separate strings of a small number of solar cells (22) results in a lower reverse voltage across the shaded solar cell, which means that the reverse breakdown voltages of the solar cells in the string need not be very high, which means that a lower grade of silicon such as metallurgical silicon can be used to make the solar cells, with attendant cost reduction.

In the embodiment shown, when the bypass diodes (36) are utilized to bypass a string 80-92 when at least one solar cell is not producing sufficient power, for example if at least one solar cell (22) in the string is shaded, all of the solar cells within the string are bypassed. Thus the power produced by any working solar cells (22), for example unshaded solar cells, in the bypassed string is lost. Accordingly, strings with fewer solar cells (22) in each string require fewer solar cells to be bypassed resulting in lower power losses during partial power production conditions such as partial shading. Thus, in the embodiment shown, because the strings 80-92 have a relatively low number of solar cells (22) in each string, the apparatus (10) during partial power production conditions, such as partial shading, may still produce a greater amount of power than would a similar apparatus with a higher number of solar cells in each string.

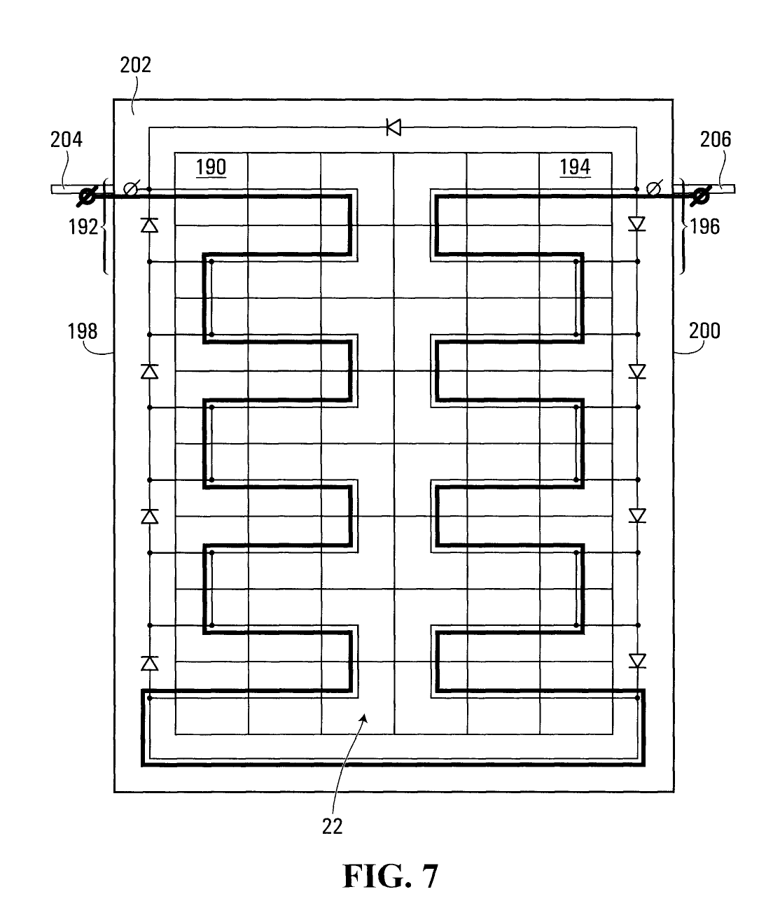

Other solar cell string arrangements are possible, as shown in FIGS. 7, 8 and 9. Referring to FIG. 7 in an alternative embodiment, the solar cells (22) are arranged into strings similar to that shown in FIGS. 1 and 4, with the exception that a first solar cell 190 of a first string 192 and the last solar cell 194 of the last string 196 are disposed adjacent opposite edges 198, 200 of a substrate 202 and the bottom two rows of solar cells act as the bottom string. Positive and negative terminating conductors 204 and 206 are arranged to extend out of opposite side edges 198, 200 of the apparatus 10. This facilitates the use of very short connecting conductors to connect adjacent solar panels of similar type together side-by-side adjacently, in a series of solar panels.

In the embodiment shown there are 6 solar cells (22) in each string. As discussed above, this relatively low number of solar cells (22) in each string allows the solar cells to be made from a low grade of silicon such as metallurgical silicon and reduces the power loss of the apparatus (10) during partial power production conditions such as partial shading.

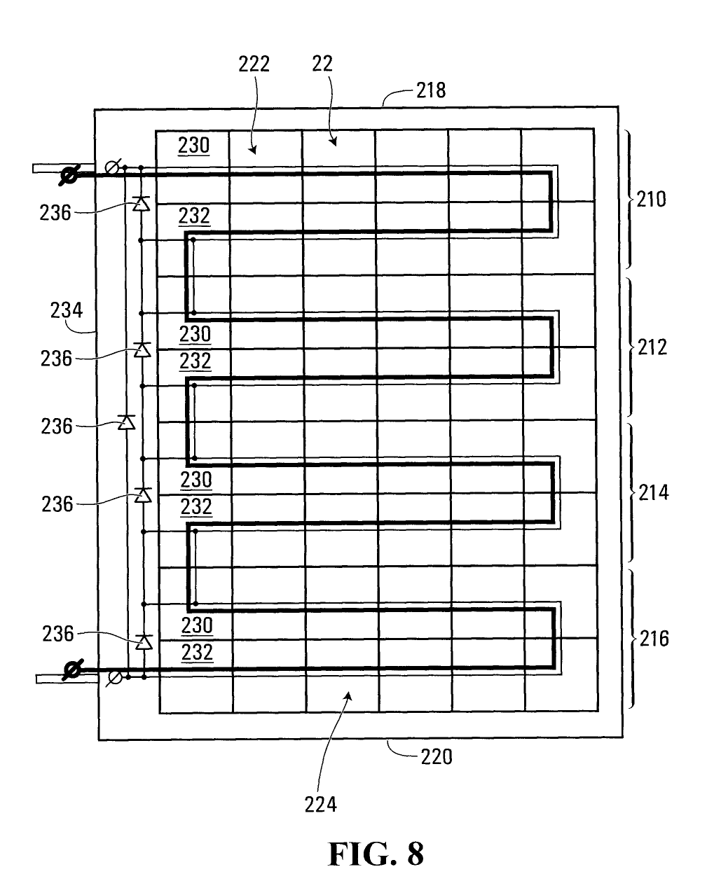

Referring to FIG. 8 the solar cells 22 are connected together in strings 210, 212, 214, and 216 wherein the strings are electrically connected in a series such that the series has a first string 210 and a last string 216 disposed at opposite ends 218, 220 of the solar panel. In the embodiment shown, the first string 210 is disposed at a top portion 222 of the panel and the last string 216 is disposed at a bottom portion 224 of the panel. Alternatively, (not shown) the first string 210 may be disposed at the bottom portion 224 of the panel and last string may be disposed at the top portion 222 of the panel. Both of these arrangements permit first and last solar cells 230, 232 of each string 210, 212, to be positioned adjacent the same portion of the perimeter margin, e.g. adjacent the same edge 234, which permits the heat generated in the bypass diodes 236 to be dissipated at a common edge.

In the embodiment shown, there are 12 solar cells (22) in each string 210, 212, 214, and 216. This relatively high number of solar cells (22) in each string 210, 212, 214, and 216 raises the maximum reverse voltage that may occur on a solar cell (22) during shading. Accordingly in the embodiment shown, solar cells (22) made of low grade silicon such as metallurgical silicon may not have sufficient reverse breakdown voltage values and solar grade silicon may be required for making the solar cells (22) in the strings 210, 212, 214, and 216.

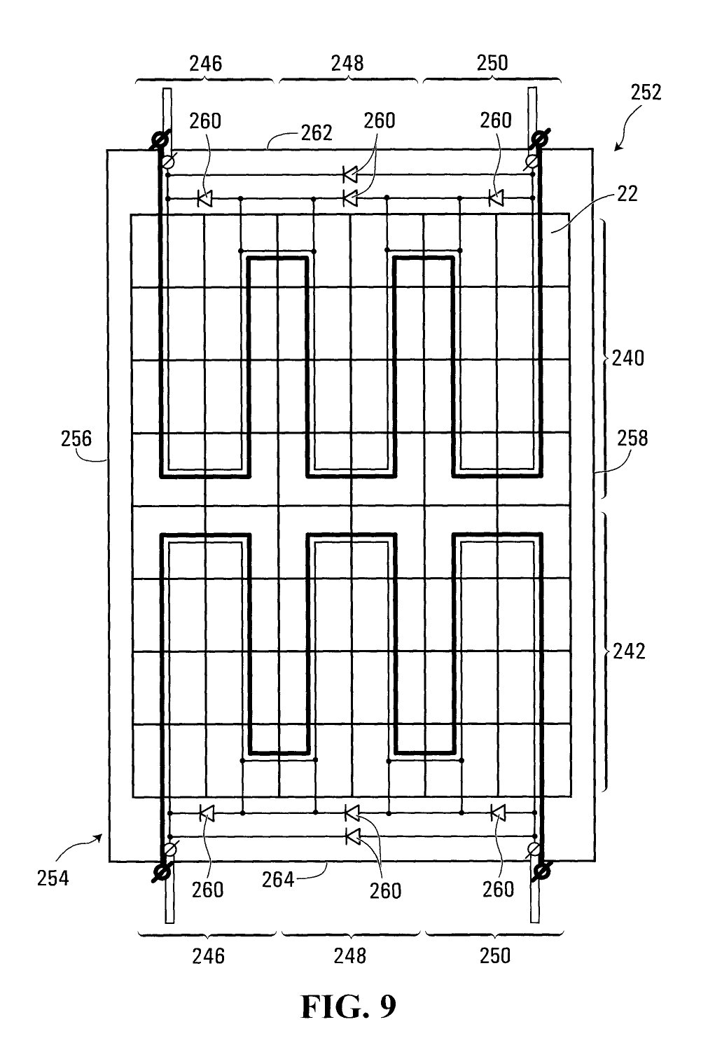

Referring to FIG. 9 in an alternative embodiment, strings of solar cells 22 are electrically connected in a series group comprising a plurality of separate sub-groups. In this embodiment there are two subgroups 240 and 242, each sub-group comprising three strings 246, 248, and 250 comprising 8 solar cells (22) each for a total of 24 solar cells in each sub-group. The first sub-group 240 is located in a top portion 252 of the solar panel and the second sub-group 242 is located in a bottom portion 254 of the solar panel. The first string 246 and the last string 250 of each group are disposed at opposite sides 256, 258 of the solar panel. This provides essentially two separate solar cell units within a single panel and positions bypass diodes 260 in portions of a perimeter margin adjacent top and bottom edges 262, 264 of the panel.

Of course other string arrangements are possible, where, in general, the first and last solar cells of each string are positioned adjacent the perimeter margin to permit electrical conductors and bypass diodes for each of the strings in the solar panel to be located in the perimeter margin, where heat produced by the bypass diodes can be easily dissipated.

Other aspects and features of the present invention will become apparent to those ordinarily skilled in the art upon review of the above description of specific embodiments of the invention in conjunction with the accompanying figures.

The embodiments of the invention in which an exclusive property or privilege is claimed are defined as follows:

1. A solar panel apparatus comprising:
a transparent sheet substrate having front and rear planar faces and a perimeter edge extending all around a perimeter of said substrate;
a plurality of solar cells arranged into a planar array on said rear face such that light operable to activate said solar cells can pass though said substrate to activate said solar cells and such that a perimeter margin is formed on said rear face of said substrate, adjacent said perimeter edge;
a plurality of electrical conductors arranged generally end to end in said perimeter margin;
a plurality of electrodes electrically connecting said solar cells together into a plurality of series strings of solar cells, each series string having a positive terminal and a negative terminal electrically connected to respective ones of an adjacent pair of electrical conductors adjacent to each other, in said perimeter margin; and
a plurality of bypass diodes, each of said bypass diodes being electrically connected between a respective said pair of electrical conductors to shunt current from a corresponding string connected to said respective pair of electrical conductors when a solar cell of said corresponding string is shaded.

2. The apparatus of claim 1 wherein said strings are electrically connected in a series, such that said series has a first string and a last string and wherein a first solar cell of said first string and a last solar cell of said last string are disposed proximally adjacent each other.

3. The apparatus of claim 2 wherein said first solar cell of said first string and said last solar cell of said last string are disposed adjacent a common edge of said substrate.

4. The apparatus of claim 2 wherein said strings are electrically connected together by electrodes, to form said series.

5. The apparatus of claim 1 wherein said bypass diodes include planar diodes.

6. The apparatus of claim 1 further comprising heat sinks to dissipate heat caused by electric current flowing in respective said bypass diodes.

7. The apparatus of claim 6 wherein said electrical conductors include respective heat sink portions that act as said heat sinks and wherein in operation, respective said bypass diodes have a thermal gradient defining a hot side and a cold side thereof and wherein said respective said bypass diodes have a hot side terminal and a cold side terminal emanating from said hot side and said cold side respectively and wherein said hot side terminal is connected to a respective said heat sink portion of a respective one of said electrical conductors.

8. The apparatus of claim 7 wherein said respective said heat sink portions include respective generally flat portions of said electrical conductors.

9. The apparatus of claim 8 wherein said electrical conductors are comprised of a first type of metallic foil strip and wherein said generally flat portions have a thickness of between about 50 μm to about 1000 μm and a width of between about 3 mm to about 13 mm and a length of between about 3 cm to about 200 cm.

10. The apparatus of claim 9 further comprising terminating conductors associated with respective said bypass diodes, said terminating conductors comprising a metallic foil strip of a second type having a thickness less than said thickness of said generally flat portion of said metallic foil strip of said first type and a length less than said length of said generally flat portion of said metallic foil strip of said first type, said metallic strip of said second type having a first end connected to a respective one of said electrical conductors and a second end connected to said cold side of a respective said bypass diode.

11. The apparatus of claim 10 wherein said metallic foil strip of said second type has a thickness of between about 30 um to about 200 um, a width approximately the same as said width of said metallic foil of said first type and a length of between about 3 cm to about 10 cm.

12. The apparatus of claim 6 wherein said electrical conductors are formed from a first type of metallic foil strip having a thickness of between about 30 μm to about 200 μm and a width of between about 3 mm to about 13 mm and a length of between about 3 cm to about 200 cm and wherein said heat sinks include respective metallic foil strips of a second type electrically connected to respective said metallic foil strips of said first type, said metallic foil strips of said second type having a thickness greater than the thickness of said metallic foil strips of said first type.

13. The apparatus of claim 12 wherein said metallic foil strip of said second type has a width approximately the same as said width of said metallic foil strip of said first type and a length less than the length of said metallic foil strip of said first type.

14. The apparatus of claim 13 wherein said metallic foil strip of said second type is on a portion of a respective metallic foil strip of said first type.

15. The apparatus of claim 14 wherein in operation, respective said bypass diodes have a thermal gradient defining a hot side and a cold side thereof and wherein said respective said bypass diodes have a hot side terminal and a cold side terminal emanating from said hot side and said cold side respectively and wherein said hot side terminal is electrically connected to a respective said metallic foil strip of said second type and said cold side terminal is electrically connected to a respective said metallic foil strip of said first type.

16. The apparatus of claim 15 wherein said metallic foil strip of said second type has a thickness of between about 50 μm to about 1000 μm and a width approximately equal to the width of said metallic foil strip of said first type and a length of between about 3 cm to about 10 cm.

17. The apparatus of claim 2 further comprising a backing covering said solar cells, said electrical conductors and said bypass diodes, such that said solar cells, said electrical conductors and said bypass diodes are laminated between said front substrate and said backing to form a laminate

18. The apparatus of claim 17 wherein said backing has an impregnated heat conducting material operable to conduct heat from said heat sinks and said bypass diodes.

19. The apparatus of claim 18 wherein said backing comprises aluminum-impregnated Tedlar®.

20. The apparatus of claim 18, further comprising a heat conductive frame on said perimeter edge.

21. The apparatus of claim 18 wherein said first and last strings have respective terminals that extend from between said front substrate and said backing, to extend from an edge of said laminate.

22. The apparatus of claim 2 wherein said solar cells are arranged in rows and columns on said substrate and wherein said apparatus has a bottom and a top, wherein said bottom is operable to be mounted lower than said top when the solar panel apparatus is in use, and wherein solar cells in a bottom row located at said bottom are electrically connected by said electrodes to define a bottom string of solar panels.

23. The apparatus of claim 22 wherein solar cells in at least first and second rows of said solar cells, above said bottom row and in at least some of said columns of said solar cells common to said bottom row, are electrically connected together to define a mid-string of solar cells, wherein said mid-string includes a first solar cell and a last solar cell at opposite poles of said mid-string, and wherein said first and last solar cells of said mid-string are in a same column of said solar cells and are in adjacent rows of said solar cells.

24. The apparatus of claim 23 wherein said plurality of series strings includes a plurality of said mid strings.

25. The apparatus of claim 24 wherein at least some of said mid-strings are disposed side by side.

26. The apparatus of claim 23 wherein said first solar cell of said first string and said last solar cell of said last string are disposed at the top of said substrate.

27. A method of protecting a string of solar cells from shading in a solar panel having a plurality of strings of solar cells, the method comprising: causing electric current to be shunted around any string of said solar cells having at least one shaded solar cell by shunting said electric current through electrical conductors and a bypass diode located in a perimeter margin of a substrate supporting said solar cells such that no matter which string has a shaded solar cell current through the string with the shaded solar cell is shunted through electrical conductors and a respective bypass diode located in the perimeter margin, to thereby distribute dissipation of heat from respective bypass diodes that are associated with strings having at least one shaded solar cell, to different locations around said perimeter margin.

28. The method of claim 27 wherein causing electric current to be shunted comprises:
arranging a plurality of solar cells into a planar array on a rear face of a transparent sheet substrate having front and rear faces and a perimeter edge extending all around a perimeter of said substrate, such that light can pass though said substrate to activate said solar cells and such that said perimeter margin is formed on said rear face of said substrate adjacent said perimeter edge;
using a plurality of electrodes to electrically connect said solar cells together into a plurality of series strings of solar cells wherein each series string has a positive terminal and a negative terminal;
arranging a plurality of said electrical conductors end-to-end in said perimeter margin;
electrically connecting said positive and negative terminals to respective ones of an adjacent pair of said electrical conductors adjacent to each other in said margin; and
electrically connecting bypass diodes to respective pairs of said adjacent said electrical conductors.

29. The method of claim 28 wherein electrically connected said strings comprises connecting said solar cells such that said series has a first string and a last string and such that a first solar cell of said first string and a last solar cell of said last string are disposed proximally adjacent each other.

30. The method of claim 29 wherein electrically connecting said solar cells comprises connecting said solar cells such that said first solar cell of said first string and said last solar cell of said last string are disposed adjacent a common edge of said substrate.

31. The method of claim 27 further comprising dissipating heat caused by electric current shunted through said bypass diode.

32. The method of claim 31 wherein dissipating heat comprises electrically and thermally connecting said bypass diode to a heat sink.

33. The method of claim 24 further comprising laminating said solar cells, said electrical conductors and said bypass diodes between said substrate and a backing to form a laminate.

34. The method of claim 33 further comprising dissipating heat from said bypass diodes through said backing.

35. The method of claim 33, further comprising conducting heat from said backing and from said substrate to a heat conducting frame on a perimeter edge of said substrate.

36. The method of claim 33 further comprising causing terminals connected to said first and last solar cells of said first and last strings respectively to extend from between said front substrate and said backing, to extend from an edge of said laminate.

37. The method of claim 28 wherein arranging said solar cells comprises arranging said solar cells in rows and columns on said substrate such that a string of said solar cells is located in a bottom row of said solar cells.

38. The method of claim 37 wherein arranging said solar cells comprises arranging said solar cells such that solar cells in at least first and second rows of said solar cells, above said bottom row and in at least some of said columns of said solar cells common to said bottom row, are electrically connected together to define a mid-string of solar cells, wherein said mid-string includes a first solar cell and a last solar cell at opposite poles of said mid-string, and wherein said first and last solar cells of said mid-string are in a same column of said solar cells and are in adjacent rows of said solar cells.

39. The method of claim 38 wherein arranging comprises arranging said solar cells such that a plurality of mid-strings are disposed side by side.

40. The method of claim 38 wherein arranging comprises arranging said solar cells such that said first solar cell of said first string and said last solar cell of said last string are disposed at the top of said substrate.
